(19) United States
(12) Patent Application Publication
(10) Pub. No.: US 2011/0244689 A1
(43) Pub. Date: Oct. 6, 2011

(54) METHOD OF MANUFACTURING SEMICONDUCTOR DEVICE

(75) Inventors: So-ra Han, Bucheon-si (KR); Yool Kang, Yongin-si (KR); Seong-ho Moon, Yongin-si (KR); Kyung-hwan Yoon, Yongin-si (KR); Hyoung-hee Kim, Hwaseong-si (KR); Seong-woon Choi, Suwon-si (KR); Seok-hwan Oh, Seoul (KR)

(73) Assignee: SAMSUNG ELECTRONICS CO., LTD., Suwon-si (KR)

(21) Appl. No.: 13/076,856

(22) Filed: Mar. 31, 2011

(30) Foreign Application Priority Data
Mar. 31, 2010 (KR) 1020100029346

(51) Int. Cl. H01L 21/311

(52) U.S. Cl. 438/702; 438/703; 257/E21.257

(57) ABSTRACT

A method of manufacturing a semiconductor device includes forming a first mask pattern on a substrate by using a material including a polymer having a protection group de-protectable by an acid, the first mask pattern having a plurality of holes; forming a capping layer on an exposed surface of the first mask pattern, the capping layer including an acid source; diffusing the acid source into the first mask pattern so that the protection group becomes de-protectable from the polymer in the first mask pattern; forming a second mask layer on the capping layer, the second mask layer separate from the first mask pattern and filling the plurality of holes in the first mask pattern; and forming a plurality of second mask patterns in the plurality of holes by removing the capping layer and the first mask pattern.

### CROSS-REFERENCE TO RELATED APPLICATIONS

This application claims the benefit of Korean Patent Application No. 10-2010-0029346, filed on Mar. 31, 2010, in the Korean Intellectual Property Office, the disclosure of which is incorporated herein in its entirety by reference.

### BACKGROUND

1. Field

The inventive concepts relate to a method of manufacturing a semiconductor device, and more particularly, to a method of manufacturing a semiconductor device by using an exposure process.

2. Description of the Related Art

As integration of semiconductor devices has rapidly increased, fine patterning has become more significant. In order to integrate many devices in a narrow area, the size of an individual element should be made as small as possible. To this end, a pitch that is the sum of a width of each of the patterns to be formed and a distance between the patterns should be small. Recently, as a design rule of semiconductor devices has been reduced, there is a limitation in forming patterns having a fine pitch due to a resolution limitation in a photolithography process for forming patterns for implementing a semiconductor device. For example, when a plurality of island-shaped fine patterns are formed using a photolithography process, as a value of a normalized image log-slope (NILS) is decreased during an exposure process, obtaining patterns having a desired shape is difficult.

### SUMMARY

The present invention provides a method of manufacturing a semiconductor device, whereby, when a plurality of island-shaped fine patterns are formed, fine patterns having a desired shape are more easily formed by improving a value of a normalized image log-slope (NILS) during a photolithography process and by improving resolution.

According to an example embodiment of the inventive concepts, there is provided a method of manufacturing a semiconductor device. A first mask pattern is formed on a substrate by using a material including a polymer having a protection group de-protectable by an acid, the first mask pattern having a plurality of holes. A capping layer is formed on an exposed surface of the first mask pattern, the capping layer including an acid source. The acid source is diffused into the first mask pattern so that the protection group becomes de-protectable from the polymer in the first mask pattern. A second mask layer is formed on the capping layer, separate from the first mask pattern, and filling the plurality of holes in the first mask pattern. A plurality of second mask patterns is formed in the plurality of holes by removing the capping layer and the first mask pattern.

The capping layer may include a water-soluble polymer and the acid source, and the acid source may include one selected from the group consisting of an acid, a potential acid and combinations thereof. The forming the capping layer may include coating a capping composition including a water-soluble polymer, an acid source and deionized water on the first mask pattern; and annealing the coated capping composition by attaching materials included in the capping composition to a surface of the first mask pattern.

The annealing the capping composition may be performed until the acid source is diffused into the first mask pattern. The diffusing may include applying heat to diffuse the acid source of the capping layer into the first mask pattern. In order to remove the capping layer and the first mask pattern, the capping layer and the first mask pattern may be dissolved using an alkaline aqueous solution. The forming the second mask patterns may include dissolving portions of the second mask layer using an alkaline aqueous solution until only the second mask patterns remain.

According to an example embodiment of the inventive concepts, there is provided a method of manufacturing a semiconductor device. A layer is formed on a substrate. An anti-reflective layer is formed on the layer. A first mask pattern is formed on the anti-reflective layer by using a material including a polymer having a protection group that is de-protectable by an acid, the first mask pattern having a plurality of holes. A capping layer is formed on an exposed surface of the first mask pattern, the capping layer including an acid source. The acid source is diffused into the first mask pattern. A second mask layer is formed on the anti-reflective layer, the second mask layer separate from the first mask pattern and filling the plurality of holes in the first mask pattern. A plurality of second mask patterns is formed in the plurality of holes by removing the capping layer and the first mask pattern. An anti-reflective layer pattern is formed by etching portions of the anti-reflective layer corresponding with the plurality of holes in the first mask pattern using the plurality of second mask patterns. A plurality of fine patterns is formed by etching the layer using the anti-reflective layer pattern.

The capping layer may include water-soluble polymer and the acid source, and the acid source may include one selected from the group consisting of an acid, a potential acid and combinations thereof. The forming the capping layer may include coating a capping composition including a water-soluble polymer, an acid source and deionized water on the first mask pattern and the layer; and annealing the coated capping composition. The diffusing the acid source and the forming the capping layer may be performed simultaneously.

The first mask pattern may include a first resist material, and the second mask layer may include a second resist material different from the first resist material. The method may further include etching the substrate using the plurality of fine patterns to form trenches in the substrate; and forming an isolation layer in the trenches, the isolation layer including an insulating material.

According to an example embodiment of the inventive concepts, there is provided a method of manufacturing a semiconductor device. A layer is formed on a substrate. An anti-reflective layer is formed on the layer. A first mask pattern is formed on the anti-reflective layer by using a chemical-amplification type resist material, the first mask pattern having a plurality of holes. A capping layer is formed on an exposed surface of the mask pattern by coating a capping composition including water-soluble polymer, an acid source and deionized water on the first mask pattern and the layer, and annealing the coated capping composition in order to diffuse the acid source into the first mask pattern. The capping composition remaining on the capping layer is removed. A second mask layer is formed on the anti-reflective layer, the second mask layer separate from the first mask pattern and filling the plurality of holes in the first mask pattern. The capping layer and the first mask pattern are dissolved using an alkaline aqueous solution to remove the capping layer and the first mask pattern. A plurality of second mask patterns is formed in the plurality of holes by dissolving portions of the second mask layer using the alkaline aqueous solution.

The acid source may include one selected from a group consisting of an organic acid, an inorganic acid, a thermoacid generator (TAG), a photoacid generator (PAG) and combinations thereof.

### BRIEF DESCRIPTION OF THE DRAWINGS

Example embodiments of the inventive concepts will be more clearly understood from the following detailed description taken in conjunction with the accompanying drawings in which:

FIG. 1 is a plane view illustrating an example of fine patterns that can be formed by a method of manufacturing a semiconductor device, according to an example embodiment of the inventive concepts;

FIGS. 2A through 2G are cross-sectional views for explaining the method of manufacturing a semiconductor device illustrated in FIG. 1;

FIG. 3 is a plan view illustrating the shape of a plurality of first mask patterns formed in a spatial region around a plurality of fine patterns, in the method of manufacturing a semiconductor device of FIG. 1;

FIG. 4 is a plan view illustrating a resultant structure in which a plurality of second mask patterns are formed, in the method of manufacturing a semiconductor device of FIG. 1;

FIG. 5 is a layout diagram illustrating a plurality of active regions that can be formed by performing the method of manufacturing a semiconductor device of FIG. 1;

FIGS. 6A through 6I are cross-sectional views for explaining a method of manufacturing a semiconductor device, according to another example embodiment of the inventive concepts;

FIG. 7 is a plan view illustrating the shape of mask patterns in which a plurality of holes for exposing a portion including a region in which a plurality of active regions are defined and its peripheral region, so that the portion and the peripheral region may be excluded from the first mask patterns, in the method of manufacturing a semiconductor device illustrated in FIGS. 6A through 6I; and

FIG. 8 is a plan view illustrating a resultant structure in which a plurality of second mask patterns are formed, in the method of manufacturing a semiconductor device of FIGS. 6A through 6I.

### DETAILED DESCRIPTION OF EXAMPLE EMBODIMENTS

Reference will now be made in detail to example embodiments, examples of which are illustrated in the accompanying drawings. However, example embodiments are not limited to the embodiments illustrated hereinafter, and the embodiments herein are introduced to provide a complete understanding of the scope and spirit of example embodiments. In the drawings, the thicknesses of layers and regions are exaggerated for clarity. Also, various elements and regions in the drawings are schematically marked. Thus, the inventive concepts are not limited to relative sizes or distances drawn in the accompanying drawings. Like reference numerals in the drawings denote like elements, and thus their description will be omitted.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to longitudinal sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

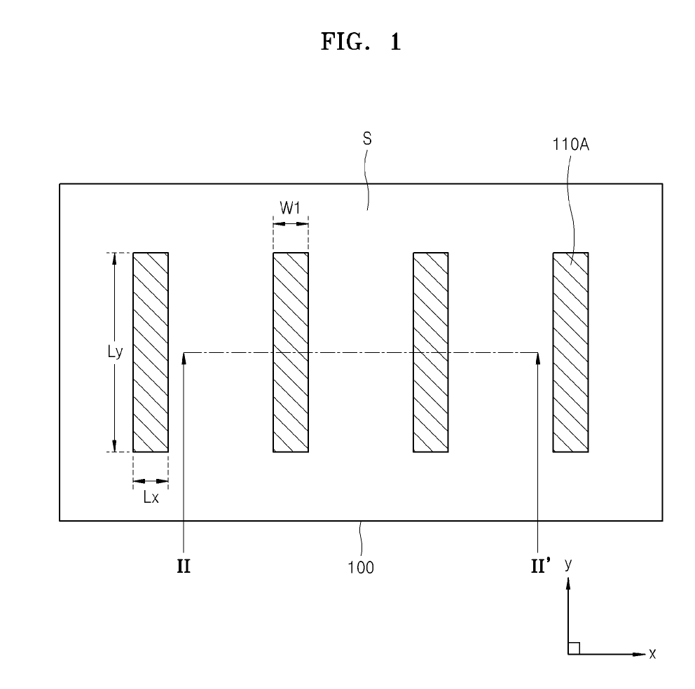

FIG. 1 is a plane view illustrating an example of fine patterns that can be formed in a method of manufacturing a semiconductor device, according to an example embodiment of the inventive concepts. Referring to FIG. 1, according to the method of manufacturing a semiconductor device according to the example embodiment, a plurality of fine patterns 110A may be formed separate from one another on a substrate 100, and have a short-axis length Lx and a long-axis length Ly.

As illustrated in FIG. 1, the plurality of fine patterns 110A have a larger long-axis length Ly than a short-axis length Lx. However, the plurality of fine patterns 110A may have nearly the same or a similar short-axis length Lx and long-axis length Ly or an even larger long-axis length Ly than a short-axis length Lx.

The plurality of fine patterns 110A may be elements for forming various unit devices in a semiconductor device. For example, the plurality of fine patterns 110A may be used as etch mask patterns in an etch process for defining conductive patterns, insulating patterns, or active regions of a semiconductor device.

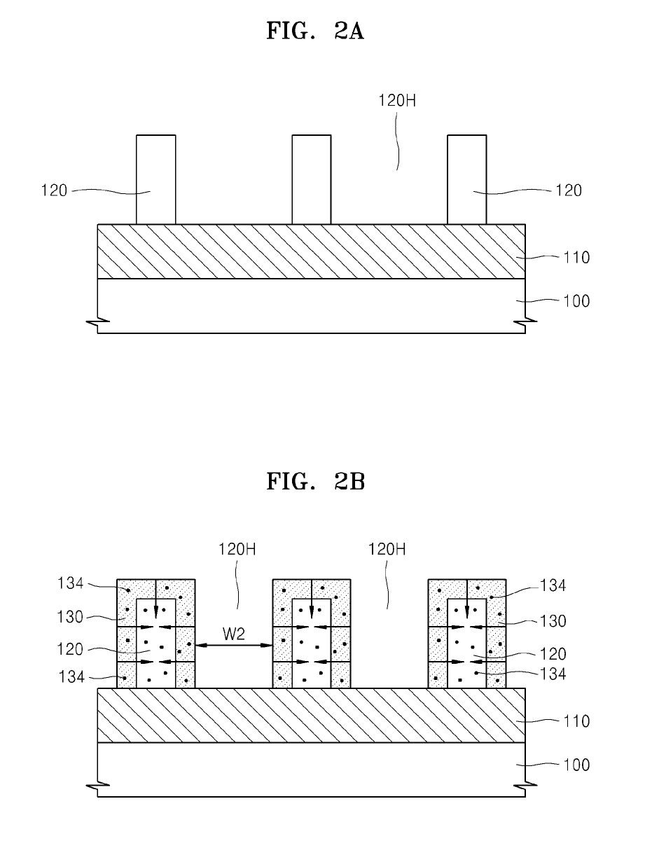

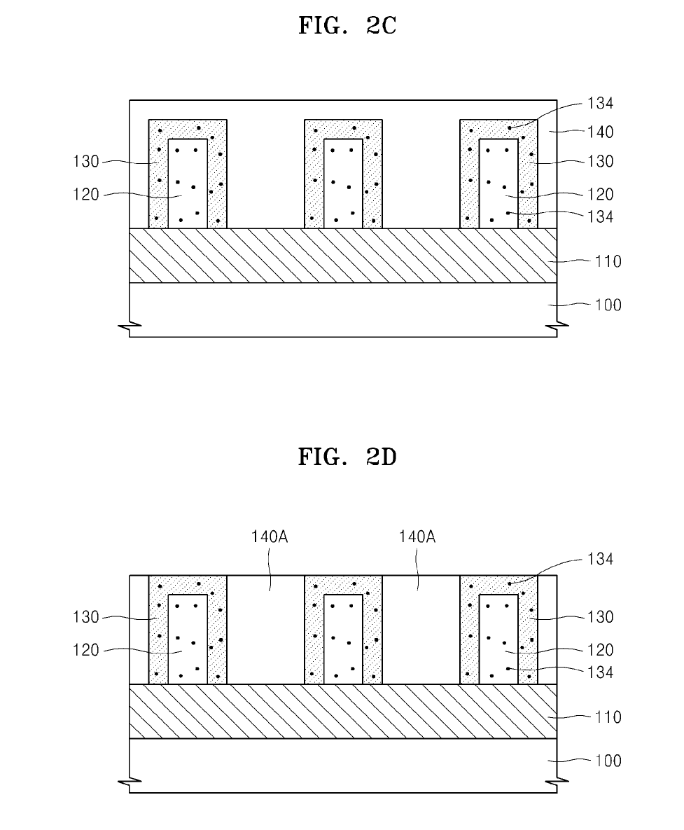

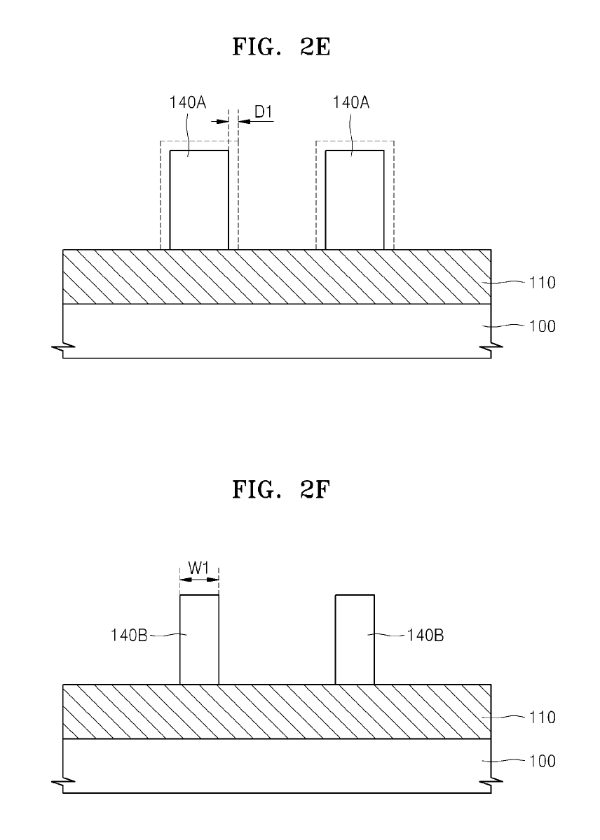

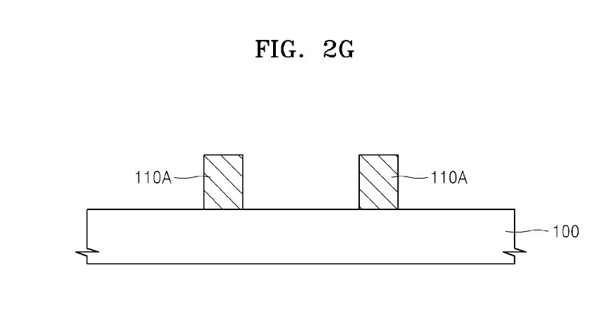

FIGS. 2A through 2G are cross-sectional views for explaining the method of manufacturing a semiconductor device illustrated in FIG. 1. An example process of forming the plurality of fine patterns 110A illustrated in FIG. 1 on the substrate 100 will be described with reference to FIGS. 2A through 2G. FIGS. 2A through 2G illustrate cross-sectional shapes of a portion corresponding to a cross-section of a line II-II′ of FIG. 1.

Referring to FIG. 2A, a layer 110 is formed on the substrate 100, and a first mask pattern 120 is formed on the layer 110. The first mask pattern 120 is formed in a spatial region S (see FIG. 1) around the plurality of fine patterns 110A on the substrate 100. The first mask pattern 120 may not overlap a region in which the plurality of fine patterns 110A (see FIG. 1) to be finally obtained are formed on the substrate 100. To this end, a plurality of holes 120H for exposing a portion including the region in which the plurality of fine patterns 110A (see FIG. 1) are formed and its peripheral region may be formed in the first mask pattern 120.

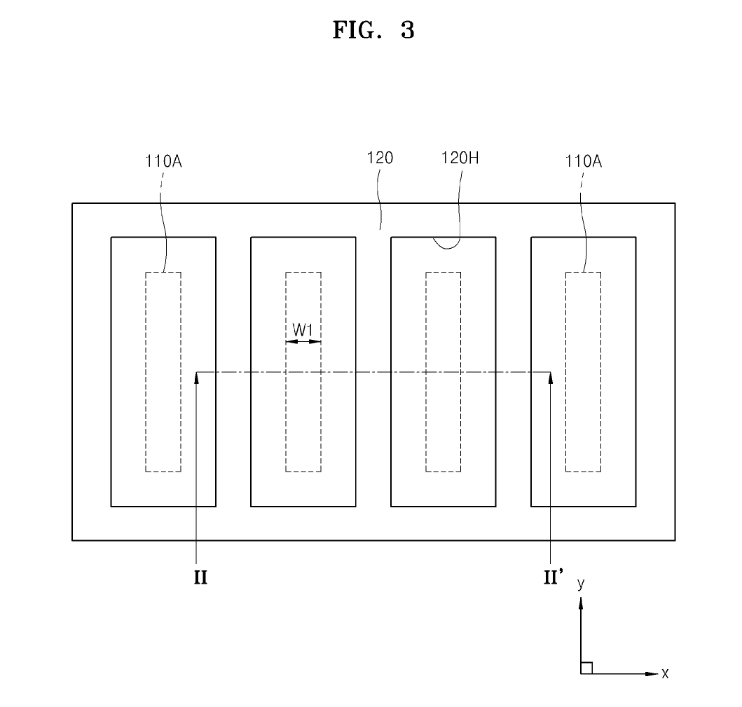

FIG. 3 is a plan view illustrating the shape of the first mask pattern 120 formed in the spatial region S around the plurality of fine patterns 110A, in the method of manufacturing a semiconductor device of FIG. 1. A plan region illustrated in FIG. 3 may correspond to a plan region illustrated in FIG. 1. The cross-sectional shape of the first mask pattern 120 in FIG. 2A may correspond to a portion corresponding to the cross-section of a line II-II′ of FIG. 3. In FIG. 3, the plurality of fine patterns 110A of FIG. 1 is marked by dotted lines.

Referring back to FIG. 2A, the substrate 100 may be a silicon substrate. The layer 110 may be formed of various materials according to the use of patterns to be formed. When a gate electrode is formed on the substrate 100, the layer 110 may be formed as a doped polysilicon layer or a stack structure of a doped polysilicon layer and a metal silicide layer, for example. When a bit line is formed on the substrate 100, the layer 110 may be formed of metal, for example, tungsten or aluminum.

Alternatively, the layer 110 may be an insulating layer to be used as a mold layer in a damascene wiring process. Also, the layer 110 may be a hard mask layer to be used as an etch mask when the substrate 100 is etched so as to define a plurality of active regions on the substrate 100. If necessary, before the first mask pattern 120 is formed, an anti-reflective layer (not shown) formed of an organic material, an inorganic material or combinations thereof may be further formed on the layer 110 to be etched.

The first mask pattern 120 may be formed of an organic material. For example, the first mask pattern 120 may be a resist pattern obtained from a general resist composition. In order to form the first mask pattern 120, for example, after a resist layer is formed by coating a photoresist material on the layer 110, the resist pattern, in which the plurality of holes 120H for exposing portions of a top surface of the layer 110 are formed, may be formed by using exposure and developing processes with respect to the resist layer according to a general photolithography process.

For example, the first mask pattern 120 may be a positive chemical-amplification type resist composition that contains a photoacid generator (PAG). For example, the first mask pattern 120 may be obtained from a KrF excimer laser (248 nm) resist composition, an ArF excimer laser (193 nm) resist composition or an EUV (13.5 nm) resist composition. The chemical-amplification type resist composition includes a polymer having a protection group that can be de-protected by an acid.

Referring to FIG. 2B, a plurality of capping layers 130 are formed to cover exposed sidewalls and top surface of the first mask pattern 120. The thickness of each of the plurality of capping layers 130 is not specifically limited. However, a width W2 of a space defined by the capping layers 130 in a given direction in the holes 120H of the first mask pattern 120, for example, in an x-direction of FIGS. 1 and 3, should not be smaller than a width W1 of the fine patterns 110A to be finally formed.

The capping layers 130 include acid sources 134. The acid sources 134 may be formed of an acid, a potential acid, or combinations thereof. For example, the capping layers 130 may be formed of mixtures of polymer and the acid sources 134.

When the acid sources 134 included in the capping layer 130 are acids, the type of acid is not specifically limited, and various types of acids may be used. The acid sources 134 may be organic or inorganic acids. For example, an acid may be one selected from the group consisting of CH₃SO₃H (sulfonic acids), C₄F₉SO₃H (perfluorobutane sulfonic acid), CF₃CO₂H (trifluoroacetic acid), and CF₃SO₃H (trifluoromethanesulfonic acid) or combinations thereof.

Alternatively, when the acid sources 134 included in the capping layers 130 are potential acids, each of the acid sources 134 may be a thermoacid generator (TAG) that generates an acid due to heat or the PAG. The TAG included in the capping layers 130 may be formed of an aliphatic or alicyclic compound. For example, the TAG may be formed of at least one compound selected from the group consisting of carbonate ester, sulfonate ester, and phosphate ester. In more detail, the TAG may be formed of at least one compound selected from the group consisting of cyclohexyl nonafluorobutanesulfonate, norbornyl nonafluorobutanesulfonate, tricyclodecanyl nonafluorobutanesulfonate, adamantyl nonafluorobutanesulfonate, cyclohexyl nonafluorobutanecarbonate, norbornyl nonafluorobutanecarbonate, tricyclodecanyl nonafluorobutanecarbonate, adamantyl nonafluorobutanecarbonate, cyclohexyl nonafluorobutanephosphonate, norbornyl nonafluorobutanephosphonate, tricyclodecanyl nonafluorobutanephosphonate, and adamantyl nonafluorobutanephosphonate.

The PAG included in the capping layers 130 may be formed of triarylsulfonium salts, diaryliodonium salts, sulfonates, or mixtures thereof. For example, the PAG may be formed of triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonates, pyrogallol tris(alkylsulfonates)), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, (triphenylsulfonium perfluorooctanesulfonate (PFOS)), diphenyliodonium PFOS, methoxydiphenyliodonium PFOS, di-t-butyldiphenyliodonium triflate, N-hydroxysuccinimide PFOS, norbornene-dicarboximide PFOS, or mixtures thereof.

The capping layers 130 may be formed of mixtures of polymer and the acid sources 134. The capping layers 130 may include 0.01 to 50 parts by weight of the acid sources 134 based on 100 parts by weight of polymer. However, the content of the acid sources 134 in the capping layers 130 is not specifically limited and may be determined according to a process design. The capping layers 130 may include a hydrophilic organic compound. Also, the capping layer 130 may include a heterocyclic compound having a nitrogen atom or a polymer having a substituent including the heterocyclic compound including the nitrogen atom.

Alternatively, the capping layers 130 may include a water-soluble polymer. A water-soluble polymer may include, for example, at least one monomer unit selected from the group consisting of an acrylamide type monomer unit, a vinyl type monomer unit, an alkylene glycol type monomer unit, a maleic anhydride monomer unit, an ethyleneimine monomer unit, a monomer unit including an oxazoline group, an acrylonitrile monomer unit, an allylamide monomer unit, 3,4-dihydropyran monomer unit, and 2,3-dihydrofuran monomer unit as a repetition unit. Alternatively, water-soluble polymer may include a copolymer including a pyrrolidone-based first repetition unit and a second repetition unit having a different structure from the first repetition unit. The second repetition unit may include at least one monomer unit selected from the group consisting of an acrylamide type monomer unit, a vinyl type monomer unit, an alkylene glycol type monomer unit, a maleic anhydride monomer unit, an ethyleneimine monomer unit, a monomer unit including an oxazoline group, an acrylonitrile monomer unit, an allylamide monomer unit, 3,4-dihydropyran monomer unit, and 2,3-dihydrofuran monomer unit.

When the heterocyclic compound having the nitrogen atom is included in a capping composition for forming the capping layers 130, the heterocyclic compound is attached to the surface of the first mask pattern 120 due to an ionic bond between a nitrogen atom included in the heterocyclic compound and a hydrogen atom exposed to the surface of the first mask pattern 120, so that the capping layers 130 may be formed.

For example, in order to form the capping layers 130, after a capping composition including a water-soluble polymer, the acid sources 134 and deionized water are spin-coated on the first mask pattern 120, annealing is performed at the temperature of about 25° C. to 180° C. for about 20 to 180 seconds, and a water-soluble polymer is attached to the surfaces of the plurality of first mask pattern 120.

As another example for forming the capping layers 130, after a capping composition including RELACS™ R-607 (Resolution Enhancement Lithography Assisted by Chemical Shrink, a product manufactured by AZ Electronic Materials), the acid sources 134 and deionized water are spin-coated on the first mask pattern 120, annealing is performed at the temperature of about 140° C. to 170° C. for about 1 minute and R-607 is attached to the surface of the first mask pattern 120, thereby forming the capping layers 130. A process of cleaning the capping composition that remains on the capping layers 130 with deionized water and removing the capping composition may be used.

The acid sources 134 are included in the capping layers 130. By performing annealing for attachment of the capping layers 130 during a process of forming the capping layers 130, the acid sources 134 included in the capping composition or the capping layers 130 may be diffused into the first mask pattern 120, as marked by a plurality of arrows in FIG. 2B. When each of the acid sources 134 is a TAG, an acid may be generated from the TAG while performing annealing in order to attach the capping layers 130. The acid generated from the TAG in this manner may be diffused into the first mask pattern 120 from the capping composition or the capping layers 130.

In some example embodiments, an annealing process for forming the capping layers 130 may be performed in a sufficient time so that the acid sources 134 from the capping composition or the capping layers 130 may be diffused into the overall portions of the first mask pattern 120. If necessary, after the capping layers 130 are attached to the surfaces of the first mask pattern 120 by the annealing process, an additional annealing process may be further performed so that the acid sources 134 may be sufficiently diffused into the first mask pattern 120.

After the capping layers 130 are formed, a residual on the surfaces of the capping layers 130 may be removed by performing a cleaning process using deionized water. After the acid sources 134 are diffused into the first mask pattern 120 from the capping composition or the capping layers 130 via the annealing process described above, protection groups of polymer that are present in the first mask pattern 120 may be de-protected by the acids obtained from the acid sources 134 that are present in the first mask pattern 120.

The capping layers 130 may allow the acid to diffuse into the first mask patterns 120. Furthermore, in a subsequent process, the capping layers 130 may prevent or reduce intermixing with the first mask pattern 120 and other layers formed on the capping layers 130 in a subsequent process, for example, a second mask layer 140 that will be described later with reference to FIG. 2C.

Referring to FIG. 2C, the second mask layer 140 is formed on the capping layers 130 so as to completely fill the holes 120H in the layer 110 to be etched. The second mask layer 140 may be formed of a resist composition. In this regard, the resist composition that constitutes the second mask layer 140 may be a positive or negative chemical-amplification type resist composition. For example, the second mask layer 140 may be obtained from an i-line (365 nm) resist composition, a KrF excimer laser (248 nm) resist composition, an ArF excimer laser (193 nm) resist composition, or an EUV (13.5 nm) resist composition.

In order to form the second mask layer 140, one resist composition selected from resist compositions described above is spin-coated on a resultant structure in which the capping layers 130 are formed, and a baking process may be performed. Since an exposure process and a process using an acid are not performed on the second mask layer 140 in a subsequent process, material that does not include a potential acid, such as a PAG or a TAG, may be used as the resist composition that constitutes the second mask layer 140.

The second mask layer 140 is formed of a material having solubility with respect to a solvent, for example, an alkaline water solution such as a standard 2.38 parts by weight tetramethylammonium hydroxide (TMAH) aqueous solution, which is lower than the solubility of the capping layers 130. For example, the second mask layer 140 may be formed of a material having solubility with respect to an alkaline water solution of about 1 to 10 Å/second. The second mask layer 140 is formed using a resist material having a relatively low dark erosion characteristic in which an unexposed resist layer is dissolved or developed with a developing agent so that solubility with respect to the developing agent of the second mask layer 140 may be lower than that of the capping layers 130.

General resist materials have a relatively low dark erosion characteristic compared to RELACS™ R-607. For example, a resist material including a polymer having a Novolac-based resist or polyhydroxy styrene (PHS) monomer unit, a polymer having an acetal protection group, or a polymer having a (meth)acrylate-based monomer unit may be used to form the second mask layer 140. Material for forming the second mask layer 140 is not specifically limited. However, since the second mask layer 140 does not require an exposure process, a material having an improved resistance to dry etching may be used to form the second mask layer 140 without the need of considering characteristics related to resolution.

In FIG. 2C, the second mask layer 140 is formed in such a way that the height of a top surface of the second mask layer 140 from a top surface of the substrate may be higher than the height of a top surface of the capping layer 130. However, the inventive concepts are not limited thereto. Although not shown, after the second mask layer 140 is formed, the height of the top surface of the second mask layer 140 may be smaller than or the same as the height of the top surface of the capping layer 130 so that the capping layers 130 may be exposed from an upper portion of the first mask pattern 120. In detail, the second mask layer 140 may be formed to be disposed only in the holes 120H. After a solution in which a resist material for forming the second mask layer 140 is dissolved in an organic solvent and spin-coated on the first mask pattern 120, a process of removing the organic solvent by using a dry or baking process may be used.

When the acid sources 134 remain on the capping layers 130, the acid sources 134 that remain on the capping layers 130 may be diffused into the second mask layer 140 by a relatively small distance. For example, when each of the acid sources 134 is a TAG, an acid that is generated from the TAG during a baking process after the resist composition is coated so as to form the second mask layer 140 may be diffused into the second mask layer 140. When each of the acid sources 134 is an acid, the acid may be diffused into the second mask layer 140 due to diffusion while the second mask layer 140 is formed. The width of second mask patterns 140A (see FIG. 2D) obtained from the second mask layer 140 in a subsequent process may be adjusted according to a distance at which the acid is diffused into the second mask layer 140.

Referring to FIG. 2D, the second mask layer 140 is dissolved from its top surface by using a solvent until the capping layers 130 are exposed according to a dark erosion characteristic of the second mask layer 140. An alkaline aqueous solution, such as a standard 2.38 parts by weight TMAH aqueous solution, may be used as the solvent.

A plurality of second mask patterns 140A are formed in the holes 120H that were formed in the first mask pattern 120 as the capping layers 130 are exposed. When the height of the top surface of the second mask layer 140 is smaller than or the same as the height of the top surface of the capping layer 130 in the process described with reference to FIG. 2C, the process of FIG. 2D may be omitted.

Referring to FIG. 2E, the exposed capping layers 130 are dissolved and removed using the solvent subsequent to the process of FIG. 2D, thereby dissolving and removing the first mask pattern 120 that is exposed as a result of dissolving and removing the exposed capping layers 130.

As described with reference to FIG. 2B, since protection groups of a polymer in the first mask pattern 120 are de-protected by the acid sources 134 diffused from the capping layers 130, the first mask pattern 120 may be well dissolved using the alkaline aqueous solution, such as a standard 2.38 parts by weight TMAH aqueous solution, and may be completely removed.

When an acid is diffused into the second mask layer 140 from the capping layers 130 while the second mask layer 140 is formed, by a given distance, the second mask layer 140 may be dissolved by a small thickness (D1) from its exposure to the alkaline aqueous solution. The small thickness (D1) is defined according to a distance at which the acid is diffused into the second mask layer 140 while the capping layers 130 and the first mask pattern 120 are removed.

Referring to FIG. 2F, the plurality of second mask patterns 140A are further dissolved using the solvent subsequent to the process of FIG. 2E, thereby removing portions of the exposed surface of the second mask patterns 140A and forming a plurality of second mask patterns 140B each having a desired width W1. When the second mask patterns 140 each have a desired width W1 in the process described with reference to FIG. 2E, the process of FIG. 2F may be omitted.

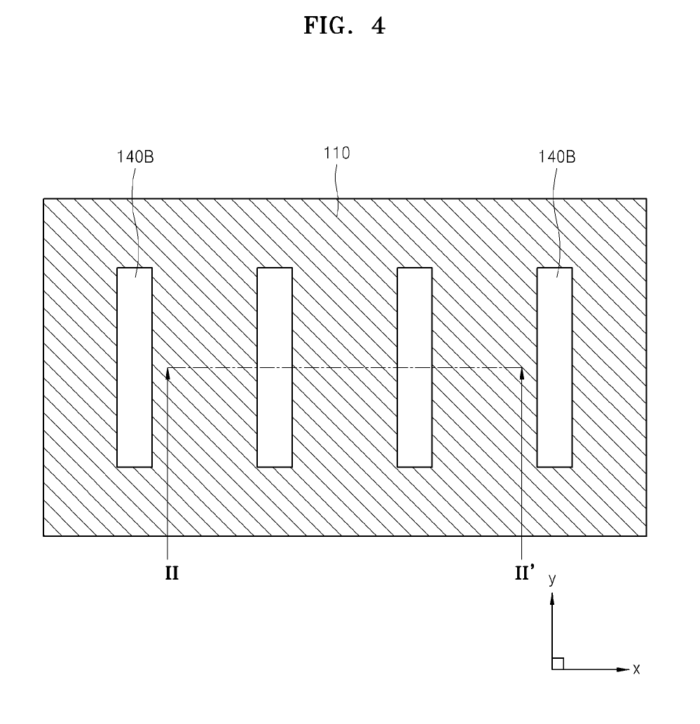

FIG. 4 is a plan view illustrating a resultant structure in which a plurality of second mask patterns are formed, in the method of manufacturing a semiconductor device of FIG. 1. A plan region illustrated in FIG. 4 may correspond to the plan region of FIG. 1, and the cross-sectional shape of the second mask patterns 140B in FIG. 2F may correspond to the cross-section of a line II-II′ of FIG. 4.

Referring to FIG. 2G, the layer 110 is etched using the plurality of second mask patterns 140B as an etch mask, thereby forming a plurality of fine patterns 110A. The plurality of fine patterns 110A may have the plan shape illustrated in FIG. 1. After the plurality of fine patterns 110A are formed, the plurality of second mask patterns 140B that remain on the plurality of fine patterns 110A are removed. In order to remove the plurality of second mask patterns 140B, ashing and strip processes may be used.

In the method of manufacturing the semiconductor device illustrated in FIG. 1, the first mask patterns 120, in which a plurality of holes 120H having a reverse shape to the plan shape of the fine patterns 110A are formed, are formed so as to form the plurality of fine patterns 110A on the substrate 100. In an exposure process for forming the first mask pattern 120 having the plurality of holes 120H in this manner, shielding patterns having a plurality of holes are formed even in a photomask used in the exposure process. The exposure process is performed through the plurality of holes formed in the shielding patterns.

Thus, when the exposure process for forming the first mask pattern 120 is performed, a relatively higher value of a normalized image log-slope (NILS) may be obtained compared to the case when an exposure process is performed using a photomask in which shielding patterns separate from one another and corresponding to the fine patterns 110A are formed. Thus, the first mask patterns 120 may have with a higher resolution. As such, the plurality of second mask patterns 140B that are self-aligned with respect to the first mask pattern 120 without performing the exposure process may be uniformly formed with improved dimension precision.

FIG. 5 is a layout diagram illustrating a plurality of active regions that can be formed by the method of manufacturing a semiconductor device according to the inventive concepts. Referring to FIG. 5, a plurality of active regions 200A are defined by an isolation layer 260. The plurality of active regions 200A include island patterns having a short-axis X1 and a long-axis Y1 that are perpendicular to each other. The short-axis X1 and the long-axis Y1 may extend in a different direction from an x-axis direction and a y-axis direction of FIG. 1, as illustrated in FIG. 1, or may extend in the same direction as the x-axis direction and the y-axis direction of FIG. 1 (not shown).

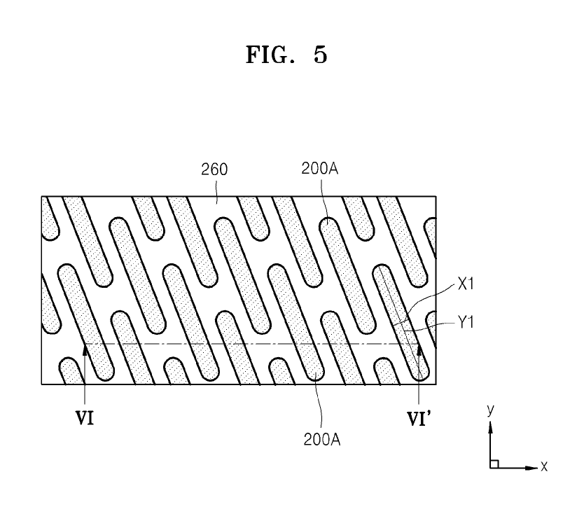

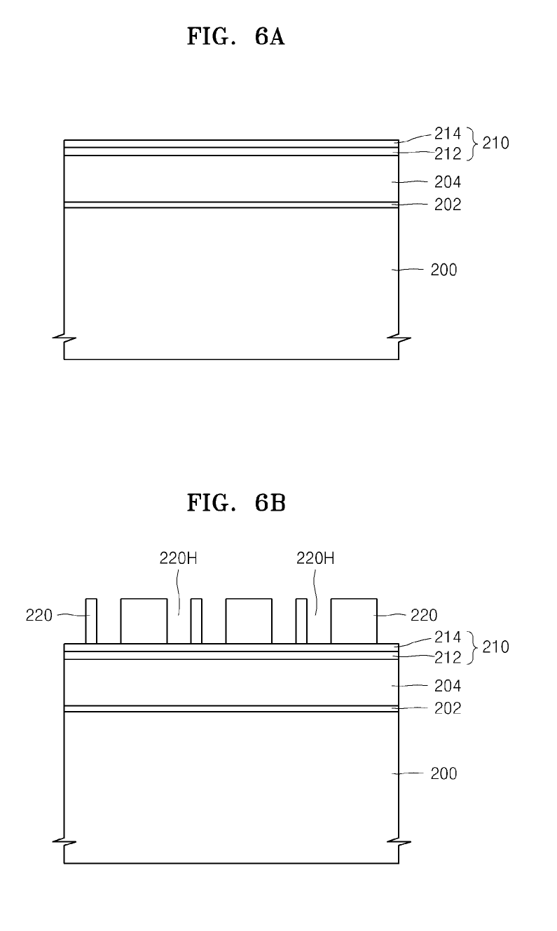

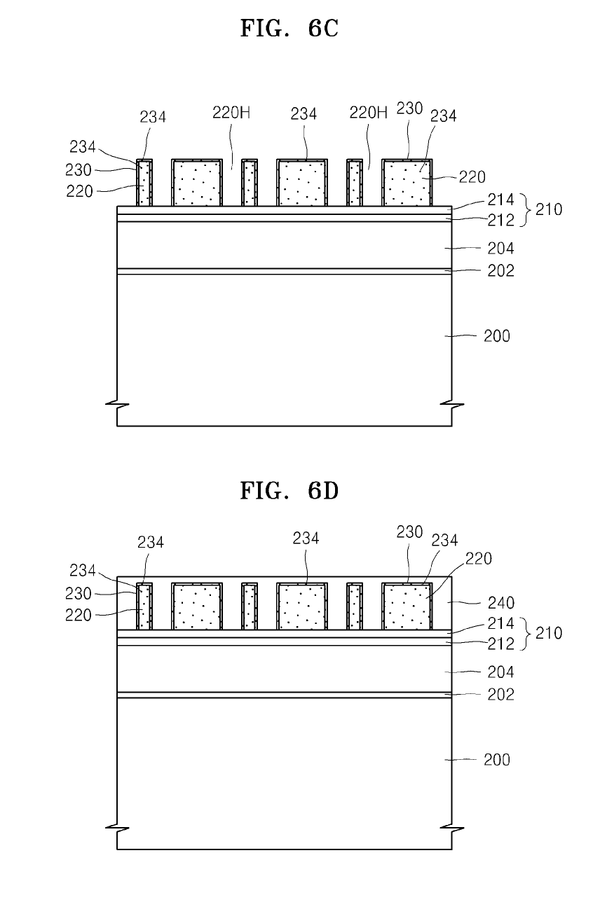

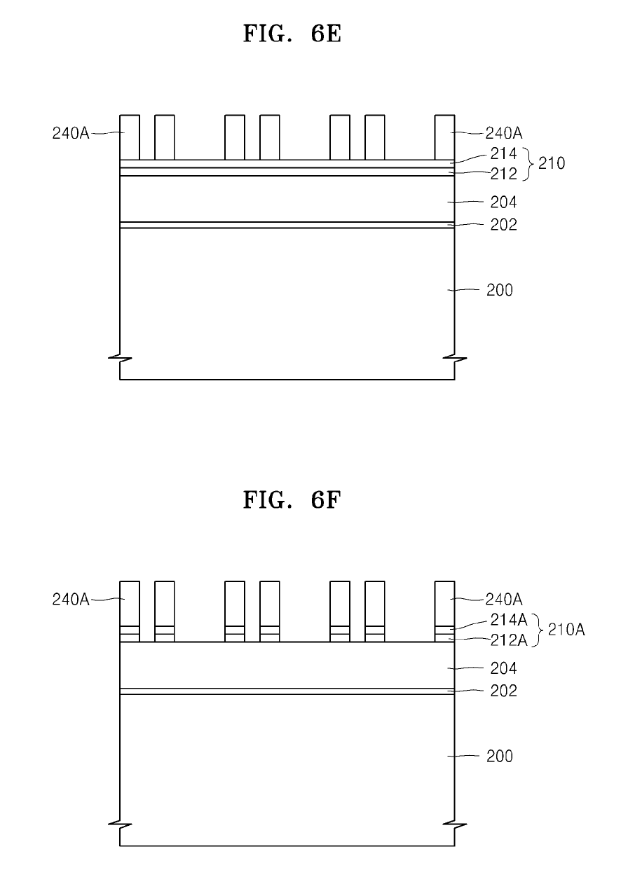

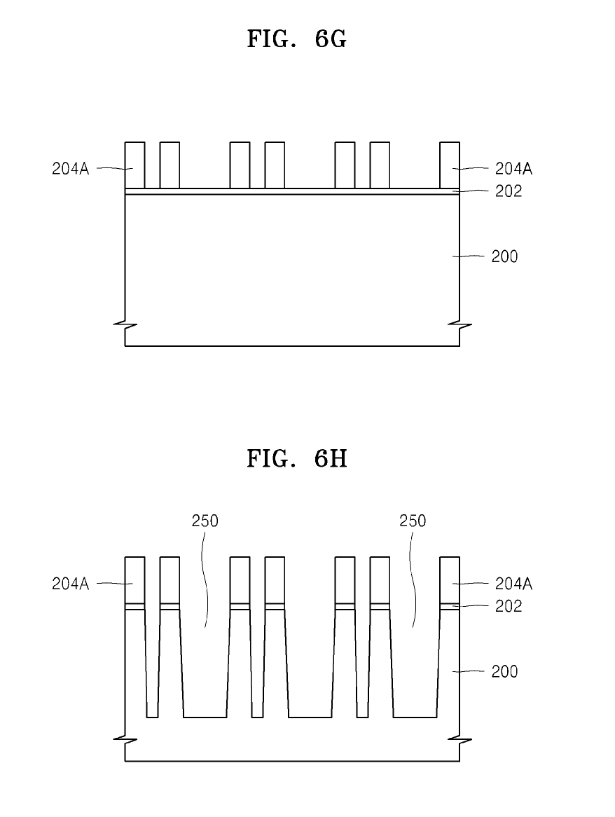

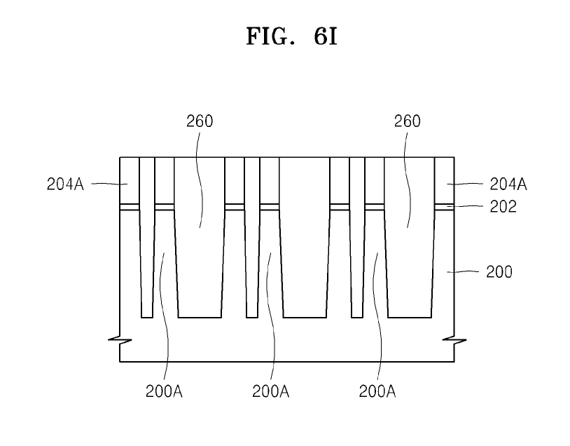

FIGS. 6A through 6I are cross-sectional views for explaining a method of manufacturing a semiconductor device, according to another example embodiment of the inventive concepts. An example process for defining the active regions 200A on a substrate 200 illustrated in FIG. 5 will be described with reference to FIGS. 6A through 6I. FIGS. 6A through 6I illustrate the cross-sectional shape of a portion corresponding to a cross-section of a line VI-VI′ of FIG. 5. In the example embodiment described with reference to FIGS. 6A through 6I, like reference numerals in FIGS. 1 through 5 represents like elements.

Referring to FIG. 6A, a pad oxide layer 202 is formed on the substrate 200. A hard mask layer 204 is formed on the pad oxide layer 202. After that, an anti-reflective layer 210 is formed on the hard mask layer 210. The substrate 200 may be a general semiconductor substrate, such as a silicon substrate. The hard mask layer 204 may be formed of a silicon nitride layer, a silicon oxide layer or combinations thereof. The anti-reflective layer 210 may have a structure in which an inorganic anti-reflective layer 212 formed of SiON and an organic anti-reflective layer 214 are sequentially stacked.

Referring to FIG. 6B, a first mask pattern 220 is formed on the anti-reflective layer 210 by using the method related to a process of forming the first mask pattern 120 described with reference to FIG. 2A. The first mask pattern 220 is formed in a spatial region between the plurality of active regions 200A on the substrate 200, i.e., in a region in which the isolation layer 260 is to be formed in a subsequent process. The first mask pattern 220 is formed on the substrate 200 so as not to overlap the active regions 200A to be defined in a later process. To this end, a plurality of holes 220H for exposing a portion including the region in which the plurality of active regions 200A (see FIG. 5) are defined and its peripheral region may be formed in the first mask pattern 220.

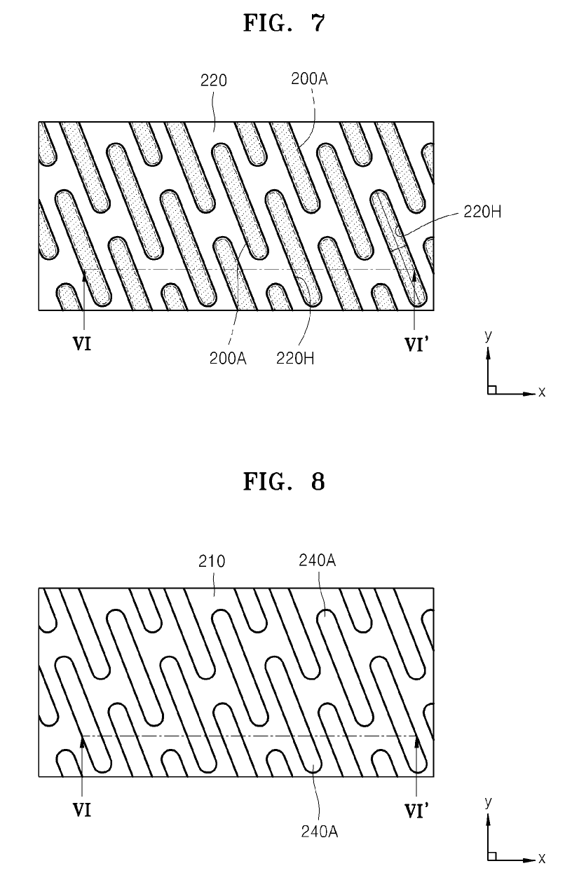

FIG. 7 is a plan view illustrating the shape of mask patterns in which the plurality of holes 220H for exposing the portion including the region in which the plurality of active regions 200A are defined and its peripheral region, so that the portion and the peripheral region may be excluded from the first mask pattern 220.

A plan region illustrated in FIG. 7 may correspond to the plan region of FIG. 5, and the cross-sectional shape of the second mask pattern 220 in FIG. 6B may correspond to the cross-section of a line VI-VI′ of FIG. 7. In FIG. 7, for explanatory convenience, the plurality of active regions 200A illustrated in FIG. 5 are marked by dotted lines. Details of the first mask pattern 220 are the same as the description of the first mask pattern 120 with reference to FIG. 2A.

Referring to FIG. 6C, a plurality of capping layers 230 that cover exposed sidewalls and a top surface of the first mask pattern 220 are formed by using the same process of forming the capping layers 130 described with reference to FIG. 2B. The capping layers 230 include acid sources 234. A detailed structure of the capping layers 230 and the acid sources 234 is the same as the description of the capping layers 130 and the acid sources 134 described with respect to FIG. 2B.

Since the acid sources 234 are included in the capping layer 230 by annealing performed for attachment of the capping layers 230 while the capping layers 230 are formed, the acid sources 234 are diffused into the first mask pattern 220, and as such, protection groups of polymers that are present in the first mask pattern 220 are de-protected by the acid sources 234 that are present in the first mask pattern 220.

Referring to FIG. 6D, a second mask layer 240 is formed on the capping layers 230 so as to completely fill the holes 220H in the anti-reflective layer 210. Details of the second mask layer 240 and its manufacturing process are the same as the description of the second mask layer 140 with reference to FIG. 2C.

Referring to FIG. 6E, by performing a series of processes of forming the second mask patterns 140B from the second mask layer 140 described with reference to FIGS. 2D through 2F, the capping layers 230 and the first mask pattern 220 are removed, and a plurality of second mask patterns 240A are formed.

FIG. 8 is a plan view illustrating a resultant structure in which a plurality of second mask patterns 240A are formed. A plan region illustrated in FIG. 8 may correspond to the plan region of FIG. 5, and the cross-sectional shape of the second mask patterns 240A in FIG. 6E may correspond to the cross-section of a line VI-VI′ of FIG. 8.

Referring to FIGS. 6E and 8, a top surface of the anti-reflective layer 210, i.e., a top surface of the organic anti-reflective layer 214, is exposed between the plurality of second mask patterns 240A. Referring to FIG. 6F, the anti-reflective layer 210, i.e., the organic anti-reflective layer 214 and the inorganic anti-reflective layer 212, are sequentially etched using the plurality of second mask patterns 240A as an etch mask, thereby forming anti-reflective layer patterns 210A having a stack structure including inorganic anti-reflective layer patterns 212A and organic anti-reflective layer patterns 214A.

Referring to FIG. 6G, the hard mask layer 204 is etched using the anti-reflective layer patterns 210A as an etch mask, thereby forming hard mask patterns 204A. After the hard mask patterns 204A are formed, portions of the second mask patterns 240A and the anti-reflective layer patterns 210A on top surfaces of the hard mask patterns 204 may be consumed. In FIG. 6G, the second mask patterns 240A and the anti-reflective layer patterns 210A do not remain on the hard mask patterns 204A. However, if necessary, after the hard mask patterns 204A are formed, portions of the anti-reflective layer patterns 210A and the second mask patterns 240A may remain on the hard mask patterns 204A.

Referring to FIG. 6H, the pad oxide layer 202 and the substrate 200 are anisotropically dry etched using the hard mask patterns 204A as an etch mask, thereby forming trenches 250 in the substrate 200.

Referring to FIG. 6I, an insulating layer is filled in the trenches 250 by using planarization using a chemical mechanical polishing (CMP) process until the hard mask patterns 204A are exposed after an insulating material is deposited in the trenches 250 and on the hard mask patterns 204A, thereby forming an isolation layer 260 formed of the insulating layer. The active regions 200A are defined by the isolation layer 260 in the substrate 200.

In the method of manufacturing a semiconductor device illustrated in FIGS. 6A through 6I, in order to define the active regions 200A in the substrate 200, the first mask patterns 220, in which the plurality of holes 220H having a reverse shape to the plan shape of the active regions 200A are formed, is first formed. In an exposure process for forming the first mask patterns 220 having the plurality of holes 220H in this manner, a shielding pattern having a plurality of holes are formed even in a photomask used in the exposure process and the exposure process is performed through the plurality of holes formed in the shielding pattern.

Thus, when the exposure process for forming the first mask pattern 220 is performed, a relatively higher value of a normalized image log-slope (NILS) may be obtained compared to the case when an exposure process is performed using a photomask in which shielding patterns separate from one another and corresponding to the fine patterns 110A are formed. Thus, the first mask pattern 220 may have a higher resolution. As such, the plurality of second mask patterns 240A that are self-aligned with respect to the first mask pattern 220 without performing the exposure process may be uniformly formed with improved dimension precision.

While the inventive concepts has been particularly shown and described with reference to example embodiments thereof, it will be understood that various changes in form and details may be made therein without departing from the spirit and scope of the following claims.

What is claimed is:

1. A method of manufacturing a semiconductor device, the method comprising:
forming a first mask pattern on a substrate by using a material including a polymer having a protection group de-protectable by an acid, the first mask pattern having a plurality of holes;
forming a capping layer on an exposed surface of the first mask pattern, the capping layer including an acid source;
diffusing the acid source into the first mask pattern so that the protection group becomes de-protectable from the polymer in the first mask pattern;
forming a second mask layer on the capping layer, the second mask layer separate from the first mask pattern and filling the plurality of holes in the first mask pattern; and
forming a plurality of second mask patterns in the plurality of holes by removing the capping layer and the first mask pattern.

2. The method of claim 1, wherein the capping layer comprises a water-soluble polymer and the acid source, and the acid source comprises one selected from the group consisting of an acid, a potential acid and combinations thereof.

3. The method of claim 2, wherein the acid comprises one selected from the group consisting of CH₃SO₃H (sulfonic acids), C₄F₉SO₃H (perfluorobutane sulfonic acid), CF₃CO₂H (trifluoroacetic acid), CF₃SO₃H (trifluoromethanesulfonic acid) and combinations thereof.

4. The method of claim 2, wherein the potential acid comprises one selected from the group consisting of a thermoacid generator (TAG), a photoacid generator (PAG) and combinations thereof.

5. The method of claim 1, wherein the forming the capping layer comprises:
coating a capping composition including a water-soluble polymer, an acid source and deionized water on the first mask pattern; and
annealing the coated capping composition by attaching materials included in the capping composition to the exposed surface of the first mask pattern.

6. The method of claim 5, wherein the annealing the capping composition is performed until the acid source is diffused into the first mask pattern.

7. The method of claim 1, wherein the second mask layer is formed from at least one of an i-line (365 nm) resist composition, a KrF excimer laser (248 nm) resist composition, an ArF excimer laser (193 nm) resist composition and an EUV (13.5 nm) resist composition.

8. The method of claim 1, wherein the diffusing includes applying heat to diffuse the acid source into the first mask pattern.

9. The method of claim 1, wherein the removing the capping layer and the first mask pattern includes dissolving the capping layer and the first mask pattern using an alkaline aqueous solution.

10. The method of claim 1, wherein the forming the second mask patterns comprises dissolving portions of the second mask layer using an alkaline aqueous solution until only the second mask patterns remain.

11. A method of manufacturing a semiconductor device, the method comprising:
forming a layer on a substrate;
forming an anti-reflective layer on the layer;
forming a first mask pattern on the anti-reflective layer by using a material including a polymer having a protection group that is de-protectable by an acid, the first mask pattern having a plurality of holes;
forming a capping layer on an exposed surface of the first mask pattern, the capping layer including an acid source;
diffusing the acid source into the first mask pattern;
forming a second mask layer on the anti-reflective layer, the second mask layer separate from the first mask pattern and filling the plurality of holes in the first mask pattern;
forming a plurality of second mask patterns in the plurality of holes by removing the capping layer and the first mask pattern;
forming an anti-reflective layer pattern by etching portions of the anti-reflective layer corresponding with the plurality of holes in the first mask pattern using the plurality of second mask patterns; and
forming a plurality of fine patterns by etching the layer using the anti-reflective layer pattern.

12. The method of claim 11, wherein the capping layer comprises water-soluble polymer and the acid source, and the acid source comprises one selected from the group consisting of an acid, a potential acid and combinations thereof.

13. The method of claim 11, wherein the forming the capping layer comprises:
coating a capping composition including a water-soluble polymer, an acid source and deionized water on the first mask pattern and the layer; and
annealing the coated capping composition.

14. The method of claim 11, wherein the diffusing the acid source and the forming the capping layer are performed simultaneously.

15. The method of claim 11, wherein the first mask pattern comprises a first resist material, and the second mask layer comprises a second resist material different from the first resist material.

16. The method of claim 11, wherein the diffusing includes applying heat to diffuse the acid source into the first mask pattern.

17. The method of claim 11, wherein the removing the capping layer and the first mask pattern includes dissolving the capping layer and the first mask pattern using an alkaline aqueous solution.

18. The method of claim 11, further comprising:
etching the substrate using the plurality of fine patterns to form trenches in the substrate; and
forming an isolation layer in the trenches, the isolation layer including an insulating material.

19. A method of manufacturing a semiconductor device, the method comprising:
forming a layer on a substrate;
forming an anti-reflective layer on the layer;
forming a first mask pattern on the anti-reflective layer by using a chemical-amplification type resist material, the first mask pattern having a plurality of holes;
forming a capping layer on an exposed surface of the mask pattern including,
coating a capping composition including a water-soluble polymer, an acid source and deionized water on the first mask pattern and the layer, and
annealing the coated capping composition in order to diffuse the acid source into the first mask pattern;
removing the capping composition remaining on the capping layer;
forming a second mask layer on the anti-reflective layer, the second mask layer separate from the first mask pattern and filling the plurality of holes in the first mask pattern;
removing the capping layer and the first mask pattern by dissolving the capping layer and the first mask pattern using an alkaline aqueous solution; and
forming a plurality of second mask patterns in the plurality of holes by dissolving portions of the second mask layer using the alkaline aqueous solution.

20. The method of claim 19, wherein the acid source comprises one selected from a group consisting of an organic acid, an inorganic acid, a thermoacid generator (TAG), a photoacid generator (PAG) and combinations thereof.
